(19) United States
(12) Patent Application Publication
(10) Pub. No.: US 2023/0136986 A1
(43) Pub. Date: May 4, 2023

(54) SILICON ETCHING LIQUID CONTAINING AROMATIC ALDEHYDE

(71) Applicant: TOKUYAMA CORPORATION, Yamaguchi (JP)

(72) Inventors: Naoto NOMURA, Yamaguchi (JP); Kosuke NORO, Yamaguchi (JP); Yoshiki SEIKE, Yamaguchi (JP); Manami OSHIO, Yamaguchi (JP); Yuichiro KAWABATA, Yamaguchi (JP); Seiji TONO, Yamaguchi (JP)

(73) Assignee: TOKUYAMA CORPORATION, Yamaguchi (JP)

(21) Appl. No.: 17/973,953

(22) Filed: Oct. 26, 2022

(30) Foreign Application Priority Data
Oct. 28, 2021 (JP) 2021-176008

(51) Int. Cl. H01L 21/465

(52) U.S. Cl. CPC H01L 21/465

(57) ABSTRACT

An object of the present invention is to provide an etching liquid having a high silicon etch selectivity with respect to silicon-germanium and a high long term stability at a processing temperature, in surface processing during the production of various semiconductor devices, especially various silicon composite semiconductor devices containing silicon-germanium, and the problem is solved by a silicon etching liquid containing an alkaline compound, an aldehyde compound, and water, the aldehyde compound being a water-soluble aromatic aldehyde.

### TECHNICAL FIELD

The present invention relates to a silicon etching liquid. More specifically, the present invention relates to an etching liquid used in silicon (Si) etching during microfabrication in the production of semiconductor devices. In particular, the present invention relates to an etching liquid useful for selectively etching silicon without etching silicon-germanium.

### BACKGROUND ART

Silicon etching is used in various steps in the production process of semiconductor devices. In recent years, silicon etching has been applied to the fabrication of structures called Fin Field-Effect Transistor (Fin-FET) and Gate all around (GAA), and this technique has become indispensable for memory cell stacking and three-dimensional construction of logic devices. As semiconductor devices become denser, silicon etching techniques used in such applications are required to offer smoother surface of wafer after etching, higher etching accuracy, and better etch selectivity to other materials. In addition, silicon etching techniques are also applied to other processes such as thinning of silicon wafers. High integration, miniaturization, high sensitivity, and/or high performance are required for these various semiconductor devices depending on the application. In order to meet these demands, silicon etching has become an important microfabrication technique in semiconductor device production.

Meanwhile, a variety of silicon etching liquids have been proposed or are actually being used. Among these silicon etching liquids, an etching liquid made of an alkaline aqueous solution is widely known and used as an anisotropic etching liquid for crystalline silicon.

Etching liquids including an alkaline aqueous solution with various additives added in addition to alkaline compounds and water have been proposed for the purpose of improving various characteristics or expressing new characteristics. An example of such an additive is reducing sugar (see, for example, Patent Documents 1 to 3). Reducing sugars are used in these silicon etching techniques to improve the silicon etch rate, or used as corrosion inhibitors to prevent etching of aluminum or aluminum alloys. It is believed that a part of a reducing sugar forms an aldehyde structure in an aqueous solution, and the aldehyde exhibits reducing properties, thereby suppressing the influence of dissolved oxygen and exhibiting the above effects.

Further, there is a proposal of adding an aldehyde to an alkaline silicon etching liquid for the purpose of capturing the hydrogen generated from dissolving silicon (for example, Patent Document 4).

Meanwhile, in recent years, the number of various silicon composite semiconductor device fabrication methods using silicon-germanium have been increasing, and these methods are sometimes used in the production of nanowires with the GAA structure described above. For example, silicon layers and silicon-germanium layers are alternately stacked by epitaxial growth on a specific substrate used as a base. Thereafter, etching is performed with only the silicon layer being used as a sacrificial layer, leaving the silicon-germanium layer as a channel layer. During this process, it is important that the etching uniformly removes only silicon without dissolving silicon-germanium, a silicon oxide film, or a silicon nitride film.

Furthermore, in memory-related applications, advances have been made regarding stacked memory cells such as 3D NAND structures, and silicon etching is sometimes used in the process of forming such structures. For example, polysilicon and silicon oxide films are alternately stacked, and a hole penetrating through the layers is formed. Then, the polysilicon exposed on the side wall of the hole is uniformly etched to form a groove. During this process, it is also important that the etching uniformly removes only silicon without dissolving a silicon oxide film or a silicon nitride film.

### PRIOR ART DOCUMENTS

### Patent Documents

Patent Document 1: JP 2006-054363 A

Patent Document 2: JP 2007-214456 A

Patent Document 3: JP 2009-206335 A

Patent Document 4: JP H10-046369 A

### SUMMARY OF INVENTION

### Technical Problem

As described above, there are many advantages to adding a reducing sugar to a silicon etching liquid including an alkaline aqueous solution. However, as a result of investigation by the present inventors, it has become clear that in an alkaline silicon etching liquid with a reducing sugar added, the pH drops rapidly during the storage, resulting in a decrease in the silicon etch rate. Typically, it is assumed that an Si etching liquid will be used repeatedly at a processing temperature. Therefore, an etch rate that changes over time is highly problematic for some applications, such as semiconductor production which requires precise etching depth (thickness).

Therefore, an object of the present invention is to provide an etching liquid having a high silicon etch selectivity with respect to silicon-germanium and a high long term stability at a processing temperature, in surface processing during the production of various semiconductor devices, especially various silicon composite semiconductor devices containing silicon-germanium.

### Solution to Problem

In view of the above problems, the present inventors have conducted intensive studies and established the following hypothesis: the decrease in pH is caused by the decomposition of reducing sugar in an alkaline environment and the generation of carboxylic acid due to the decomposition; and many of the decomposition routes of reducing sugar start from nucleophilic attacks on carbons with a hydroxyl group. Based on the hypothesis, the present inventors focused on water-soluble aromatic aldehydes, a type of compounds that are less susceptible to such attacks while having the ability to remove dissolved oxygen in a liquid. With further studies, the present inventors found that the problems described above can be solved by a silicon etching liquid containing a water-soluble aromatic aldehyde.

That is, the gist of the present invention is as follows.

[1] A silicon etching liquid comprising an alkaline compound, an aldehyde compound, and water, wherein the aldehyde compound is a water-soluble aromatic aldehyde.

[2] The silicon etching liquid according to [1], wherein the water-soluble aromatic aldehyde is a benzaldehyde derivative.

[3] The silicon etching liquid according to [1] or [2], wherein the alkaline compound is a quaternary ammonium hydroxide.

[4] The silicon etching liquid according to [1] or [2], further containing an organic solvent.

[5] A method of producing a semiconductor device, the method including bringing the silicon etching liquid according to [1] or [2] in contact with silicon.

[6] The method of producing a semiconductor device according to [5], the method comprising bringing the silicon etching liquid in contact with silicon-germanium.

[7] A method of processing silicon wafer, the method comprising bringing the silicon etching liquid according to [1] or [2] in contact with a surface of a silicon wafer.

[8] A method of processing a substrate having a silicon film, the method comprising bringing the silicon etching liquid according to [1] or [2] in contact with a surface of a substrate having a silicon film.

A first embodiment of the present invention is a silicon etching liquid containing an alkaline compound, an aldehyde compound, and water, the aldehyde compound being a water-soluble aromatic aldehyde.

A second embodiment of the present invention is a method of producing a semiconductor device, the method including bringing the silicon etching liquid according to the first embodiment in contact with silicon.

A third embodiment of the present invention is a method of processing a silicon wafer, the method including bringing the silicon etching liquid according to the first embodiment in contact with a surface of a silicon wafer, or a method of processing a substrate having a silicon film, the method including bringing the silicon etching liquid according to the first embodiment in contact with a surface of a substrate having a silicon film.

### Effects of Invention

The silicon etching liquid according to an embodiment of the present invention has good long term stability during continuous use while offering the same advantages as the silicon etching liquid including an alkaline aqueous solution to which an aldehyde compound such as a reducing sugar is added. As such, using the etching liquid according to an embodiment of the present invention enables the production of a semiconductor device or the like at a high productivity.

### DESCRIPTION OF EMBODIMENTS

Embodiments of the present invention will be described in detail below, but the present invention is not limited to the description as long as the gist of the present invention is observed. In addition, the present invention can be modified and implemented in any manner that does not depart from the gist of the present invention.

In the present specification, a numerical range expressed using “from” and “to” refers to a range including the numerical value before “to” as the lower limit and the numerical value after “to” as the upper limit, and “from A to B” or “A to B” means from A to B, inclusive.

### 1. Silicon Etching Liquid

A silicon etching liquid according to a first embodiment contains an alkaline compound, water, and a water-soluble aromatic aldehyde as essential components. First, the first embodiment will be described.

### (1) Alkaline Compound

The alkaline compound in the present embodiment can be a known alkaline compound that can be used in a silicon etching liquid. Examples of the alkaline compound include inorganic alkaline compounds such as NaOH, KOH, and ammonia, as well as organic alkaline compounds such as quaternary ammonium hydroxides and various amines.

Such alkaline compounds can be selected and used according to their distinctive known characteristics and depending on the target and purpose of silicon etching. However, depending on the target, the influence of metals such as alkali metals may not be preferable; from the viewpoint of suppressing the influence of such metals, the alkaline compound is preferably an organic alkaline compound. Among these, the alkaline compound is more preferably a quaternary ammonium hydroxide or a tertiary amine because of a significantly better long term stability of the resulting silicon etching liquid, and particularly preferably a quaternary ammonium hydroxide because of a remarkable long term stability of the resulting silicon etching liquid.

When the alkaline compound is a quaternary ammonium hydroxide, the alkaline compound is preferably a quaternary ammonium hydroxide represented by Formula (1) below.

R¹¹R¹²R¹³R¹⁴N⁺.OH⁻ (1)

where R¹¹, R¹², R¹³ and R¹⁴ is each independently a hydrocarbon group having carbon number from 1 to 16, and these hydrocarbon groups can have a substituent.

The hydrocarbon group can be linear, branched, or cyclic. In addition, the hydrocarbon group can be aliphatic, aromatic, or a combination thereof. Furthermore, when the hydrocarbon group has a substituent, examples of the substituent include a hydroxy group, an alkoxy group, an amino group, and a halogen atom, of which the substituent is particularly preferably a hydroxy group.

An aliphatic group (alkyl group) having carbon number from 1 to 16 is preferably an unsubstituted alkyl group, for example, a methyl group, an ethyl group, a n-propyl group, a i-propyl group, a n-butyl group, a i-butyl group, a sec-butyl group, or a tert-butyl group; or an alkyl group having carbon number from 1 to 4 such as an alkyl group substituted with a hydroxy group, for example, a hydroxymethyl group, a hydroxyethyl group, a hydroxy-n-propyl group, a hydroxy-i-propyl group, a hydroxy-n-butyl group, a hydroxy-i-butyl group, a hydroxy-sec-butyl group, or a hydroxy-tert-butyl group.

Examples of the aromatic group (aryl group) include a phenyl group. Examples of the hydrocarbon group that is a combination of aliphatic and aromatic hydrocarbon groups include a benzyl group. When the hydrocarbon group has an aromatic ring in the structure as described above, the hydrocarbon group preferably has carbon number from 6 to 10.

From the viewpoint of solubility, a total number of carbons in R¹¹, R¹², R¹³ and R¹⁴ is preferably 20 or less. Further, among the hydrocarbon groups described above, R¹¹, R¹², R¹³ and R¹⁴ are particularly preferably an alkyl group having carbon number from 1 to 4 or an alkyl group having carbon number from 1 to 4 substituted with a hydroxy group. The alkyl group having carbon number from 1 to 4 is preferably a methyl group, an ethyl group, a propyl group, a butyl group, or an isobutyl group. The alkyl group substituted with a hydroxy group is preferably a hydroxyethyl group. Also, at least three of R¹¹, R¹², R¹³ and R¹⁴ are preferably the same alkyl group. Of these, the alkyl group is most preferably a trimethyl group, a triethyl group, a tripropyl group, or a tributyl group.

Preferred examples of the quaternary ammonium hydroxide represented by Formula (1) include one or more types selected from the group consisting of tetramethylammonium hydroxide (TMAH), tetraethylammonium hydroxide (TEAH), ethyltrimethylammonium hydroxide (ETMAH), tetrapropylammonium hydroxide (TPAH), tetrabutylammonium hydroxide (TBAH), trimethyl-2-hydroxyethylammonium hydroxide (choline hydroxide), dimethylbis(2-hydroxyethyl)ammonium hydroxide, methyltris(2-hydroxyethyl)ammonium hydroxide, phenyltrimethylammonium hydroxide, and benzyltrimethylammonium hydroxide. More preferred examples of the quaternary ammonium hydroxide represented by Formula (1) include one or more types selected from the group consisting of TMAH, TEAH, ETMAH, TPAH, and TBAH.

As for the various amines, a primary amine, a secondary amine, or a tertiary amine can be used. However, as described above, a tertiary amine is preferred because the resulting etching liquid is less likely to degrade.

Examples of the primary amine or the secondary amine include one or more types selected from the group consisting of ethylenediamine, 1,3-diaminopropane, 1,4-diaminobutane, 1,5-diaminopentane, 1,6-diaminohexane, 1,7-diaminoheptane, 1,8-diaminooctane, 1,1,3,3-tetramethylguanidine, diethylenetriamine, dipropylenetriamine, bis(hexamethylene)triamine, N,N,N-trimethyldiethylenetriamine, N,N-bis(3-aminopropyl)ethylenediamine, 2-(2-aminoethoxy)ethanol, 2-amino-2-methyl-1-propanol, 4-amino-1-butanol, 5-amino-1-pentanol, 6-amino-1-hexanol, N-(2-aminoethyl)propanolamine, N-(2-hydroxypropyl)ethylenediamine, azetidine, pyrrolidine, piperidine, hexamethyleneimine, pentamethyleneimine, and octamethyleneimine.

Specific examples of the tertiary amine include one or more types selected from the group consisting of 2-(dimethylamino)ethanol, 3-(dimethylamino)-1-propanol, 4-dimethylamino-1-butanol, 2-(diethylamino)ethanol, triethylamine, methylpyrrolidine, methylpiperidine, 1,8-diazabicyclo[5.4.0]undec-7-ene, and 1,5-diazabicyclo[4.3.0]non-5-ene. More preferred examples of the primary amine or the secondary amine include one or more types selected from the group consisting of ethylenediamine, 1,3-diaminopropane, 1,4-diaminobutane, 1,5-diaminopentane, 1,6-diaminohexane, 1,1,3,3-tetramethylguanidine, diethylenetriamine, dipropylenetriamine, bis(hexamethylene)triamine, 2-(2-aminoethoxy)ethanol, 2-amino-2-methyl-1-propanol, 4-amino-1-butanol, 5-amino-1-pentanol, 6-amino-1-hexanol, N-(2-aminoethyl)propanolamine, pyrrolidine, piperidine, hexamethyleneimine, and pentamethyleneimine. Even more preferred examples of the primary amine or the secondary amine include one or more types selected from the group consisting of ethylenediamine, 1,3-diaminopropane, 1,4-diaminobutane, 1,5-diaminopentane, 1,6-diaminohexane, 1,1,3,3-tetramethylguanidine, diethylenetriamine, dipropylenetriamine, bis(hexamethylene)triamine, 2-(2-aminoethoxy)ethanol, 2-amino-2-methyl-1-propanol, pyrrolidine, and piperidine.

Note that, although a silicon etching liquid made of an alkaline aqueous solution allows for anisotropic etching of silicon, there may be occasions when it is desirable to suppress the anisotropy of etching while enjoying the various advantages of a silicon etching liquid made of an alkaline aqueous solution. In such a case, an alkali with a large cation size can be used. Considering the influence of three-dimensional structure, generalization is not possible, but such an effect can be easily obtained by using a quaternary ammonium cation having a total of 8 or more, preferably 9 or more constituent atoms (usually nitrogen atoms and carbon atoms, and sometimes also oxygen atoms) excluding hydrogen atoms, or by using an amine having a total of 5 or more, preferably 7 or more carbon atoms and nitrogen atoms. More preferably, the effect of suppressing the anisotropy of silicon etching can be easily achieved by using one or more types selected from the group consisting of 1,4-diaminobutane, 1,5-diaminopentane, 1,6-diaminohexane, 1,1,3,3-tetramethylguanidine, dipropylenetriamine, bis(hexamethylene)triamine, pyrrolidine, piperidine, hexamethyleneimine, pentamethyleneimine, octamethyleneimine, 2-(dimethylamino)ethanol, 3-(dimethylamino)-1-propanol, 4-dimethylamino-1-butanol, 2-(diethylamino)ethanol, triethylamine, methylpyrrolidine, methylpiperidine, 1,8-diazabicyclo[5.4.0]undec-7-ene, and 1,5-diazabicyclo[4.3.0]non-5-ene. Even more preferably, the effect of suppressing the anisotropy of silicon etching can be easily achieved by using one or more types selected from the group consisting of 1,4-diaminobutane, 1,1,3,3-tetramethylguanidine, dipropylenetriamine, bis(hexamethylene)triamine, pyrrolidine, piperidine, 2-(dimethylamino)ethanol, 2-(diethylamino)ethanol, triethylamine, methylpyrrolidine, and methylpiperidine.

More specifically, the effect of suppressing the anisotropy of silicon etching can be easily achieved by using TPAH or TBAH as the quaternary ammonium hydroxide, or by using one or more types selected from the group consisting of 1,4-diaminobutane, 1,5-diaminopentane, 1,6-diaminohexane, 1,7-diaminoheptane, 1,8-diaminooctane, 1,1,3,3-tetramethylguanidine, dipropylenetriamine, bis(hexamethylene)triamine, N,N,N-trimethyldiethylenetriamine, N,N-bis(3-aminopropyl)ethylenediamine, pyrrolidine, piperidine, hexamethyleneimine, pentamethyleneimine, octamethyleneimine, 2-(dimethylamino)ethanol, 3-(dimethylamino) propanol, 4-dimethylamino-1-butanol, 2-(diethylamino)ethanol, triethylamine, methylpyrrolidine, methylpiperidine, 1,8-diazabicyclo[5.4.0]undec-7-ene, and 1,5-diazabicyclo[4.3.0]non-5-ene as the amine.

Meanwhile, using an alkali with a small cation size, such as tetramethylguanidine or TMAH, can increase the silicon etch rate.

A concentration of the alkaline compound in the silicon etching liquid according to the present embodiment, although not limited, is preferably in a range from 0.05 to 2.2 mol/L because the silicon etching liquid with such alkaline compound concentration offers excellent etching effect without crystal precipitation. The concentration of the alkaline compound in the silicon etching liquid according to the present embodiment is more preferably from 0.1 to 1.2 mol/L, particularly preferably 1.0 mol/L or less.

In the present embodiment, one type of alkaline compound can be used alone, or a plurality of different types of alkaline compounds can be used in combination.

### (2) Water

The silicon etching liquid according to the present embodiment contains water as an essential component. The etch rate is also affected by the amount of water. In general, a proportion of water in the silicon etching liquid is preferably 30 mass % or greater, more preferably 50 mass % or greater, although the proportion varies depending on the types and amounts of other components.

### (3) Water-Soluble Aromatic Aldehyde

An aldehyde compound is essential for the silicon etching liquid according to the present embodiment. Here, the most important feature of the present embodiment is that a water-soluble aromatic aldehyde is used as the aldehyde compound.

In the present embodiment, the water-soluble aromatic aldehyde is a compound in which a formyl group is directly bonded to an aromatic ring, the compound having a solubility in water at 25° C. of 1.2 mass % or greater.

When the solubility of the compound is less than 1.2 mass %, the effect of adding aldehyde, particularly the effect of improving the silicon etch selectivity with respect to silicon-germanium cannot be sufficiently obtained; the reason is inferred to be the property that low solubility in water means high hydrophobicity. The solubility is preferably 3 mass % or greater, more preferably 5 mass % or greater.

Aromatic aldehydes are generally represented by Formula (2) below.

Ar—C(═O)H (2)

where Ar is an aryl group or a heteroaryl group.

In the formula above, Ar is an aryl group or a heteroaryl group; specifically, Ar is a group (ring) derived from an aromatic ring compound such as a benzene ring, a naphthalene ring, a pyridine ring, a pyrrole ring, an imidazole ring, a furan ring, a thiophene ring, or an oxazole ring. However, when Ar is an aromatic hydrocarbon ring such as a benzene ring or a naphthalene ring, the solubility in water mentioned above cannot be achieved without substitution (other than the formyl group). As such, further substitution with one or more types of hydrophilic groups (groups that improve water solubility) selected from a hydroxy group and an amino group is necessary. Meanwhile, when Ar is a heterocycle such as a pyridine ring, the water solubility described above is expressed even without substitution in many cases, but even in such cases, further substitution with a hydrophilic group can be employed. Furthermore, substitution with one or more types selected from an alkyl group, an alkoxyl group, an acyl group, and a halogen atom can be employed as long as the water solubility described above can be achieved.

From the perspectives of the effect on the level of water solubility, the effect on the silicon etch rate, availability, and the like, the water-soluble aromatic aldehyde in this embodiment is preferably a compound in which the above-mentioned Ar is a benzene ring having a substituent (that is, the water-soluble aromatic aldehyde in this embodiment is preferably a benzaldehyde derivative). Among these, the water-soluble aromatic aldehyde in this embodiment is particularly preferably a compound in which the substituent in the benzene ring is a hydroxy group.

Specific examples of the water-soluble aromatic aldehyde that can be used in the present embodiment include one or more types selected from the group consisting of 2-pyridinecarboxaldehyde, helicin, 3-hydroxybenzaldehyde, 2,3-dihydroxybenzaldehyde, 2,4-dihydroxybenzaldehyde, 2,5-dihydroxybenzaldehyde, 3,4-dihydroxybenzaldehyde, 3,5-dihydroxybenzaldehyde and 3,4,5-trihydroxybenzaldehyde. More preferred examples of the water-soluble aromatic aldehyde that can be used in the present embodiment include one or more types selected from the group consisting of 3-hydroxybenzaldehyde, 2,3-dihydroxybenzaldehyde, 2,4-dihydroxybenzaldehyde, and 2,5-dihydroxybenzaldehyde.

To sufficiently suppress the etch rate of silicon-germanium, a content of the water-soluble aromatic aldehyde in the silicon etching liquid according to the present embodiment is preferably from 0.1 to 30 mass %, more preferably from 0.2 to 15 mass %, and particularly preferably from 0.3 to 5 mass %.

### (4) Other Components

The silicon etching liquid according to the present embodiment can further include a known component contained in a silicon etching liquid made of an alkaline aqueous solution.

For example, the silicon etching liquid according to the present embodiment preferably contains an organic solvent, and specific examples of the organic solvent include one or more types of water-soluble or water-miscible organic solvents selected from the group consisting of: a compound having a plurality of hydroxyl groups, such as ethylene glycol, propylene glycol, dipropylene glycol, or other glycols, or glycerin; alkylene glycol monoalkyl esters, such as ethylene glycol monopropyl ether, ethylene glycol monomethyl ether, diethylene glycol monoethyl ether, propylene glycol monomethyl ether, propylene glycol monoethyl ether, and diethylene glycol n-butyl ether; and an ether having a plurality of ether bonds, such as diethylene glycol dimethyl ether, diethylene glycol methyl ethyl ether, and diethylene glycol diethyl ether. In addition, the silicon etching liquid according to the present embodiment can contain: corrosion inhibitors, such as hydroquinone, catechol, t-butylcatechol, pyrogallol, gallic acid esters, p-ethoxyphenol, o-methoxyphenol, and other phenolic compounds; various surfactants; and/or sugars.

Furthermore, the silicon etching liquid according to the present embodiment can contain one or more types of quaternary ammonium halogen salts and/or quaternary ammonium BF₄ salts selected from the group consisting of tetramethylammonium chloride, ethyltrimethylammonium iodide, dodecyltrimethylammonium bromide, and decyltrimethylammonium bromide.

### (5) Physical Properties of Silicon Etching Liquid

The silicon etching liquid containing the components described above is alkaline. A higher pH is preferred for obtaining a higher etch rate. The pH of the silicon etching liquid is preferably from 10.0 to 14.0, more preferably from 11.0 to 14.0. Note that this pH refers to the value measured at 25° C. by the glass electrode method.

The silicon etching liquid according to the present embodiment is preferably a homogeneous solution in which all of the components blended are dissolved. Furthermore, to prevent contamination during etching, the silicon etching liquid according to the present embodiment preferably contains 100/mL or less, more preferably 50/mL or less, of particles having a size of 200 nm or greater.

From the viewpoint of preventing contamination of an etching target, concentrations of metal impurities are also preferably as low as possible, and specifically, the concentrations of Ag, Al, Ba, Ca, Cd, Cr, Cu, Fe, K, Li, Mg, Mn, Na, Ni, Pb, and Zn are all preferably 1 ppb or less. Noted that when a metallic compound such as NaOH or KOH is used as the alkaline compound, attention should be given to ensure that the metal which is a constituent of the alkaline compound is not an impurity.

Furthermore, any of the metals mentioned above is, on a weight basis, preferably 1 ppb or less, more preferably 0.5 ppb or less, even more preferably 0.2 ppb or less, and most preferably 0.1 ppb or less. Further, among the metals described above, one or more types of metals selected from the group consisting of Cu, Fe, Mn, Cr, and Zn is, on a weight basis, preferably from 0.01 ppt to 1 ppb, more preferably from 0.01 ppt to 0.5 ppb, further preferably from 0.01 ppt to 0.2 ppb, and most preferably from 0.01 ppt to 0.1 ppb. Also, in the description above, ionic metals are listed as examples for a metal that can be contained in a remover, a solvent, and a treatment solution according to the present embodiment; however, the metal is not limited to these examples, and a non-ionic metal (particulate metal) can be contained, preferably in a concentration within the above range.

The silicon etching liquid according to the present embodiment can contain a gas such as hydrogen and oxygen that is, for example, derived from the silicon etching liquid or resulted from the production circumstances of the silicon etching liquid.

### 2. Method of Producing Silicon Etching Liquid

The method of producing the silicon etching liquid according to the present embodiment is not limited, and can be any method in which the alkaline compound and the water-soluble aromatic aldehyde are mixed with water to a predetermined concentration and dissolved uniformly.

The alkaline compound and the water-soluble aromatic aldehyde preferably contain as little as possible metal impurities, such as those described above, or insoluble impurities; commercially available alkaline compounds and water-soluble aromatic aldehydes can be used after being purified as necessary by, for example, recrystallization, column purification, ion exchange purification, distillation, sublimation, or filtration treatment. When a quaternary ammonium hydroxide is used as the alkaline compound, the quaternary ammonium hydroxide is preferably an extremely pure quaternary ammonium hydroxide for semiconductor production, which is a commercially available product. Note that a high-purity quaternary ammonium hydroxide for semiconductor production is typically sold as a solution such as an aqueous solution. In the production of the silicon etching liquid according to the present embodiment, the high-purity quaternary ammonium hydroxide solution can be mixed as-is with water, the water-soluble aromatic aldehyde, and another component added as necessary.

The water also preferably has a high purity with few impurities. An amount of impurities can be evaluated by electrical resistivity. Specifically, the water preferably has an electrical resistivity of 0.1 MΩ·cm or greater, more preferably 15 MΩ·cm or greater, and particularly preferably 18 MΩ·cm or greater. Such water with a small amount of impurities can be easily produced and/or obtained as ultrapure water for semiconductor production. Furthermore, ultrapure water is highly suitable because it contains remarkably little impurities that do not affect (or contribute little to) the electrical resistivity.

In the production of the silicon etching liquid according to the present embodiment, after mixing and dissolving the components, the resulting product is preferably passed through a filter having openings from several nanometers to several tens of nanometers to remove particles. The process of passing the resulting product through a filter can be performed multiple times as necessary.

In addition, other various known treatments that are methods for producing chemicals for semiconductor production can be applied. Examples of such treatment include reducing dissolved oxygen by bubbling with an inert gas such as high-purity nitrogen gas.

During mixing and dissolution (and storage), the container and device are preferably formed and/or coated with a material from which contaminants are less likely to be eluted into the silicon etching liquid. Examples of such material include known materials for the inner wall of containers containing chemicals for semiconductor production, with specific examples being polyfluoroethylene and high-purity polypropylene. The container and device are preferably cleaned in advance.

### 3. Method of Producing Semiconductor Device

A second embodiment of the present invention is a method of producing a semiconductor device, the method including bringing the silicon etching liquid according to the first embodiment in contact with silicon. The second embodiment will be described below.

In addition to bringing the silicon etching liquid according to the first embodiment in contact with silicon, the method of producing a semiconductor device according to the second embodiment can employ a known method of producing a semiconductor device. For example, the method of producing a semiconductor device according to the second embodiment can contain a known step used in a method of producing a semiconductor, such as one or more steps selected from a wafer fabrication step, an oxide film formation step, a transistor formation step, a wiring formation step, and a CMP step. Also, the method of producing a semiconductor device according to the second embodiment preferably includes bringing the silicon etching liquid according to the first embodiment in contact with silicon-germanium.

The step of bringing the silicon etching liquid according to the first embodiment in contact with silicon is not limited as long as the silicon etching liquid and silicon come into contact, but the etching liquid is preferably used as an etching liquid used in the production of a semiconductor device, such as a silicon device, that includes etching one or more types selected from the group consisting of a silicon wafer, a silicon single crystal film, a polysilicon film, and an amorphous silicon film. The silicon single crystal film includes one made by epitaxial growth.

When the method of producing a semiconductor device includes bringing the silicon etching liquid according to the first embodiment in contact with silicon-germanium, bringing the silicon etching liquid according to the first embodiment in contact with silicon and bringing the silicon etching liquid according to the first embodiment in contact with silicon-germanium can be separate steps; however, from the perspective of production efficiency, the silicon etching liquid according to the first embodiment is preferably brought in contact with a target containing silicon and silicon-germanium in the same step. The phrase “brought in contact with . . . in the same step” means that the silicon etching liquid is brought in contact with a target containing silicon and silicon-germanium at the same time. For example, by bringing the silicon etching liquid in contact with a device structure containing an oxide film and/or a nitride film as an insulating film and containing a structure of alternately stacked silicon films and silicon-germanium films, only silicon can be selectively removed from the device structure. In addition, a nanowire pattern structure for GAA using silicon-germanium or a memory stack structure such as 3D NAND can be fabricated while leaving in place the oxide film and/or nitride film which are insulating films.

### 4. Method of Processing Silicon Wafer or Substrate Having a Silicon Film

A third embodiment of the present invention is a method of processing a silicon wafer, the method including bringing the silicon etching liquid according to the first embodiment in contact with a surface of a silicon wafer, or a method of processing a substrate having a silicon film, the method including bringing the silicon etching liquid according to the first embodiment in contact with a surface of a substrate having a silicon film. The third embodiment will be described below.

An example of the method of processing a silicon wafer, the method including bringing the silicon etching liquid according to the first embodiment in contact with a surface of a silicon wafer, includes etching a silicon single crystal film by supplying the silicon etching liquid according to the first embodiment when etching a silicon wafer, especially various silicon composite semiconductor devices containing silicon-germanium.

An example of the method of processing a substrate having a silicon film, the method including bringing the silicon etching liquid according to the first embodiment in contact with a surface of a substrate having a silicon film, includes a method including a substrate holding step of holding a substrate having a silicon film in a horizontal position and a treatment solution supplying step of supplying the etching liquid according to the first embodiment to the main surface of the substrate while rotating the substrate about a vertical axis of rotation passing through the center of the substrate.

Another example of the method of processing a substrate having a silicon film includes a method including a substrate holding step of holding a plurality of substrates in an upright position and immersing the substrates in an upright position in the etching liquid according to the first embodiment stored in a treatment tank.

### 5. Etching Treatment

The silicon etching liquid according to the first embodiment can be suitably used in the production of a semiconductor device that includes etching a silicon single crystal film by supplying an etching liquid when etching a silicon wafer, especially various silicon composite semiconductor devices containing silicon-germanium.

A temperature of the silicon etching liquid during etching using the silicon etching liquid according to the first embodiment can be appropriately determined within a range from 20 to 95° C., preferably in a range from 35 to 90° C., depending on the desired etch rate, a shape and/or surface condition of the silicon after etching, productivity, and the like.

Etching using the silicon etching liquid according to the first embodiment is preferably carried out while degassing in vacuum or under reduced pressure or bubbling with an inert gas is performed. Such an operation can suppress or reduce the increase in dissolved oxygen during etching.

During etching using the silicon etching liquid according to the first embodiment, the object to be etched can be brought in contact with the etching liquid simply by immersing the object in the etching liquid, or by employing an electrochemical etching method in which a constant potential is applied to the object.

Examples of a target of an etching treatment according to the first embodiment include silicon single crystal, polysilicon, and amorphous silicon, which contain a silicon-germanium film that is not subject to the etching treatment and should be left in place. In addition to the silicon-germanium film, a material that is not subject to the etching treatment can include silicon oxide films, silicon nitride films, various metal films, and the like. Examples thereof include: alternating layers of silicon and silicon-germanium; a silicon-germanium film, a silicon oxide film, or a silicon nitride film formed on a silicon single crystal, with silicon or polysilicon and silicon-germanium further formed thereon; and structures patterned using these films.

### EXAMPLES

The present invention will be described below in detail using examples, but the present invention is not limited to these examples.

### 1. Evaluation Method

The physical properties of the silicon etching liquid were evaluated by the following methods.

(1) pH

A silicon etching liquid was prepared by mixing and dissolving the components and then heating for a predetermined time. Then, the pH of the prepared silicon etching liquid was measured using a benchtop pH meter (LAQUA F-73, available from Horiba, Ltd.). The pH was measured after the silicon etching liquid was stabilized at 25° C.

### (2) Silicon Etch Rate, and Etch Selectivity of Si to SiGe

100 mL of the silicon etching liquid heated to a predetermined liquid temperature was prepared, and a substrate [silicon (100 plane) film] prepared by epitaxially growing silicon (Si) on a silicon-germanium (SiGe) substrate having a size of 2×1 cm was immersed in the prepared silicon etching liquid for 15 seconds. During etching, the liquid was stirred at 1200 rpm while nitrogen bubbling was performed non-stop at 0.2 L/min. The etch rate (R′₁₀₀) was determined as follows. First, film thicknesses of the substrate before and after etching were measured using a spectroscopic ellipsometer, and calculation was performed using the difference in the film thicknesses before and after the etching treatment to give the etched amount of silicon film. Then, the etched amount was divided by the etching time to give the etch rate of the silicon (100 plane) film at the predetermined temperature.

In the same manner, a substrate (silicon-germanium film) on which silicon-germanium had been epitaxially grown on a silicon substrate having a size of 2×1 cm was immersed in the silicon etching liquid for 10 minutes, and the etch rate (R_{SiGe}) at the predetermined temperature was calculated.

The etch selectivity of silicon (100 plane) film with respect to silicon-germanium film (R′₁₀₀/R_{SiGe}) was calculated based on these measurement results.

Note that, the spectroscopic ellipsometer used has a lower limit of measurement range of film thickness change of 0.01 nm. As such, the etch rate of silicon-germanium film that can be determined by the method described above has a lower limit value of 0.001 nm/min.

### 2. Method of Preparing Silicon Etching Liquid

A predetermined amount of water, tetramethylammonium hydroxide (TMAH) as the alkaline compound in an amount that gave a molar concentration of 0.26 mol/L, and a predetermined amount of an organic additive (an aromatic aldehyde or other compounds) used in each of the examples or comparative examples were placed in a PFA beaker and heated in a water bath at 43° C. for a predetermined period of time. During the process, in order to remove dissolved oxygen in the solution, nitrogen bubbling was performed at a supply rate of 0.2 L/min for the final 30 minutes.

The silicon etching liquid heated for 1 hour simulated the silicon etching liquid in the initial stage of actual use, and the silicon etching liquid heated for over 1 hour simulated the silicon etching liquid that has been repeatedly used over a period of time.

### Reference Example, Comparative Examples 1 to 4

Silicon etching liquids were prepared by using the organic additives described in Table 1 at amounts that gave a concentration of 0.5 mass % and by heating for 1 hour. The evaluation results of the Si/SiGe etch selectivity were included in Table 1. Compared to the Si/SiGe etch selectivity in Reference Example in which an organic additive was not used, the Si/SiGe etch selectivity was not improved in Comparative Examples 1 to 3, in which the compounds used as the organic additives were water-soluble aromatic compounds but not aldehydes, nor in Comparative Example 4, in which the compound used as the organic additive was an aromatic aldehyde but had a low water solubility.

TABLE 1

| | Organic Additive | | | | | | Si/SiGe |
|---|---|---|---|---|---|---|---|
| | | Solubility | Water | Concentration | Heating | | Etch |
| | Type | (mass %) | Solubility | (mass %) | Time | pH | Selectivity |
| Reference | Not Added | | | | 1 h | 13.40 | 56 |
| Example | | | | | | | |
| Comparative | Hydroquinone | 6.5 | Good | 0.5 | 1 h | 13.40 | 47 |
| Example 1 | | | | | | | |
| Comparative | 1,2,4-Trihydroxybenzene | ≥1.2 | Good | 0.5 | 1 h | 13.20 | 36 |
| Example 2 | | | | | | | |
| Comparative | 3,4-Dihydroxybenzoic acid | 2 | Good | 0.5 | 1 h | 13.21 | 41 |
| Example 3 | | | | | | | |
| Comparative | Vanillin | 1 | Poor | 0.5 | 1 h | 13.44 | 62 |
| Example 4 | | | | | | | |

### Examples 1 to 5, Example 10, and Comparative Examples 5 to 8

Silicon etching liquids were prepared by using the organic additives described in Table 2 at amounts that gave a concentration of 0.5 mass % and by heating for the times specified in the same table; then, the prepared silicon etching liquids were evaluated.

Compared to the Si/SiGe etch selectivity in Reference Example, the Si/SiGe etch selectivity greatly improved in both Examples 1 to 5 and Example 10, in which a water-soluble aromatic aldehyde was used. Furthermore, there were almost no changes between the pHs of the silicon etching liquids in the initial stage (heated for 1 hour) and the pHs of the silicon etching liquids heated for 18 hours or 96 hours.

Meanwhile, Comparative Example 5 used propionaldehyde while Comparative Example 8 used acetaldehyde, both water-soluble aldehydes but aliphatic aldehydes. The initial Si/SiGe etch selectivity in Comparative Example 5 and Comparative Example 8 were good; however, after 18 hours of heating, the solutions underwent phase separation and could not be used as silicon etching liquids.

Furthermore, Comparative Example 6 used a reducing sugar maltose, and Comparative Example 7 used N-acetylglucosamine. The initial Si/SiGe etch selectivity in Comparative Example 6 and Comparative Example 7 were both greater than 1000, which was very good; however, after 18 hours of heating, the pHs of the solutions dropped significantly compared to those of the initial stages (dropped from 13.00 to 12.18 in Comparative Example 6 and from 13.02 to 12.46 in Comparative Example 7).

TABLE 2

| | Organic Additive | | | | | | | Si | SiGe | Si/SiGe |
|---|---|---|---|---|---|---|---|---|---|---|
| | | Solubility | Water | Concentration | Heating | | | Etch Rate | Etch Rate | Etch |
| | Type | (mass %) | Solubility | (mass %) | Time | | pH | (nm/min) | (nm/min) | Selectivity |
| Example 1 | 3,4-Dihydroxybenzaldehyde | ≥1.2 | Good | 0.5 | 1 | h | 13.34 | 135 | 0.61 | 221 |
| | | | | | 18 | h | 13.32 | N.D. | | |
| Example 2 | 3,5-Dihydroxybenzaldehyde | ≥1.2 | Good | 0.5 | 1 | h | 13.39 | 77 | 0.71 | 108 |
| | | | | | 18 | h | 13.37 | N.D. | | |
| Example 3 | 3,4,5-Trihydroxybenzaldehyde | ≥1.2 | Good | 0.5 | 1 | h | 13.20 | 62 | <0.001 | >1000 |
| | | | | | 96 | h | 13.19 | N.D. | | |
| Example 4 | Helicin | 1.8 | Good | 0.5 | 1 | h | 13.57 | 58 | 0.24 | 240 |
| | | | | | 18 | h | 13.43 | N.D. | | |
| Example 5 | 2-Pyridinecarboxaldehyde | 53 | Good | 0.5 | 1 | h | 13.42 | 16 | 0.10 | 155 |
| | | | | | 18 | h | 13.42 | N.D. | | |
| Example 10 | 2-Phthalaldehyde | 4.5 | Good | 0.1 | 1 | h | 13.46 | 127 | 0.40 | 317 |
| | | | | | 18 | h | 13.46 | N.D. | | |
| Comparative | Propionaldehyde | 35 | Good | 0.5 | 1 | h | 13.47 | 4 | <0.001 | >1000 |
| Example 5 | | | | | 18 | h | Phase- | N.D. | | |
| | | | | | | | separated | | | |
| Comparative | Maltose | 50 | Good | 3 | 1 | h | 13.00 | 155 | 0.07 | >1000 |
| Example 6 | | | | | 18 | h | 12.18 | N.D. | | |
| Comparative | N-cetylglucosamine | >10 | Good | 3.2 | 1 | h | 13.02 | 112 | 0.10 | >1000 |
| Example 7 | | | | | 18 | h | 12.46 | N.D. | | |
| Comparative | Acetaldehyde | Mix in any | Good | 0.5 | 1 | h | 13.45 | 7 | <0.001 | >1000 |

| | | | | | |
|---|---|---|---|---|---|
| Example 8 | proportion | 18 | h | Phase- | N.D. |
| | | | | separated | |

N.D. means “Not Detected”

### Examples 6 to 9

Silicon etching liquids were prepared by using the compounds described in Table 3 as the water-soluble aromatic aldehyde at amounts that gave a concentration of 0.5 mass % and by heating for the times specified in the same table; then, the prepared silicon etching liquids were evaluated. All of the etching liquids maintained a good Si/SiGe etch selectivity both in the initial stage and after heating for a long time, and the changes in the pH and the etch rate of silicon were also small.

TABLE 3

| | Organic Additive | | | | | | | Si | SiGe | Si/SiGe |
|---|---|---|---|---|---|---|---|---|---|---|
| | | Solubility | Water | Concentration | Heating | | | Etch Rate | Etch Rate | Etch |
| | Type | (mass %) | Solubility | (mass %) | Time | | pH | (nm/min) | (nm/min) | Selectivity |
| Example 6 | 3-Hydroxybenzaldehyde | ≥1.2 | Good | 0.5 | 1 | h | 13.44 | 35 | 0.08 | 417 |
| | | | | | 48 | h | 13.48 | 44 | 0.09 | 501 |
| Example 7 | 2,3-Dihydroxybenzaldehyde | ≥1.2 | Good | 0.5 | 1 | h | 13.36 | 94 | 0.92 | 102 |
| | | | | | 18 | h | 13.35 | 118 | 1.08 | 110 |
| Example 8 | 2,4-Dihydroxybenzaldehyde | ≥1.2 | Good | 0.5 | 1 | h | 13.44 | 122 | 0.39 | 309 |
| | | | | | 144 | h | 13.30 | 111 | 0.13 | 852 |
| Example 9 | 2,5-Dihydroxybenzaldehyde | ≥1.2 | Good | 0.5 | 1 | h | 13.36 | 142 | 0.74 | 192 |
| | | | | | 18 | h | 13.32 | 138 | 0.79 | 175 |

### Example 11, Comparative Example 9

Silicon etching liquids were prepared by using the organic additives described in Table 4 at amounts that gave a concentration of 0.5 mass %, further using the optional additives described, and heating for the times specified in the same table; then, the prepared silicon etching liquids were evaluated.

Compared to the Si/SiGe etch selectivity in Reference Example, the Si/SiGe etch selectivity greatly improved in Example 11, in which a water-soluble aromatic aldehyde was used. Furthermore, there was almost no change between the pH of the etching liquid in the initial stage and the pH of the etching liquid heated for 18 hours.

Meanwhile, Comparative Example 9 used acetaldehyde, a water-soluble aldehyde but an aliphatic aldehyde. The initial Si/SiGe etch selectivity in Comparative Example 9 was good; however, after 18 hours of heating, the solution underwent phase separation and could not be used as a silicon etching liquid.

TABLE 4

| | Organic Additive | | | | Optional Additive | |
|---|---|---|---|---|---|---|
| | | Solubility | Water | Concentration | | Concentration |
| | Type | (mass %) | Solubility | (mass %) | Type | (mass %) |
| Example 11 | 3-Hydroxybenzaldehyde | ≥1.2 | Good | 0.5 | Ethylene glycol | 40 |
| Comparative | Acetaldehyde | Mix in any | Good | 0.5 | Ethylenediamine | 0.1 |
| Example 9 | | proportion | | | tetraacetic acid | |

| | | | | Si | SiGe | Si/SiGe |
|---|---|---|---|---|---|---|
| | Heating | | | Etch Rate | Etch Rate | Etch |
| | Time | | pH | (nm/min) | (nm/min) | Selectivity |
| Example 11 | 1 | h | 13.11 | 50 | 0.18 | 275 |
| | 18 | h | 13.00 | N.D. | | |
| Comparative | 1 | h | 13.47 | 6 | 0.02 | 287 |

| | | | | |
|---|---|---|---|---|
| Example 9 | 18 | h | Phase- | N.D. |
| | | | separated | |

N.D. means “Not Detected”

This application claims the benefit of Japanese Patent Application No. 2021-176008, filed Oct. 28, 2021, which is hereby incorporated by reference herein in its entirety.

What is claimed is:

1. A silicon etching liquid comprising an alkaline compound, an aldehyde compound, and water, wherein the aldehyde compound is a water-soluble aromatic aldehyde.

2. The silicon etching liquid according to claim 1, wherein the water-soluble aromatic aldehyde is a benzaldehyde derivative.

3. The silicon etching liquid according to claim 1, wherein the alkaline compound is a quaternary ammonium hydroxide.

4. The silicon etching liquid according to claim 1, further comprising an organic solvent.

5. A method of producing a semiconductor device, the method comprising bringing the silicon etching liquid according to claim 1 in contact with silicon.

6. The method of producing a semiconductor device according to claim 5, the method comprising bringing the silicon etching liquid in contact with silicon-germanium.

7. A method of processing silicon wafer, the method comprising bringing the silicon etching liquid according to claim 1 in contact with a surface of a silicon wafer.

8. A method of processing a substrate having a silicon film, the method comprising bringing the silicon etching liquid according to claim 1 in contact with a surface of a substrate having a silicon film.
